(19) United States
(12) Patent Application Publication
(10) Pub. No.: US 2016/0071961 A1
(43) Pub. Date: Mar. 10, 2016

(54) METHOD FOR FABRICATING THIN FILM TRANSISTOR AND APPARATUS THEREOF

(71) Applicant: Au Optronics Corporation, Hsinchu (TW)

(72) Inventors: Liang-Yu Lin, New Taipei City (TW); Chun-Cheng Cheng, Hsinchu City (TW)

(21) Appl. No.: 14/622,929

(22) Filed: Feb. 16, 2015

(30) Foreign Application Priority Data
Sep. 10, 2014 (TW) 103131192

(51) Int. Cl. H01L 29/66; C30B 35/00; H01L 29/24; C30B 33/00; H01L 21/441; H01L 21/02

(52) U.S. Cl. CPC H01L 29/66969; H01L 21/441; H01L 21/02628; H01L 21/02614; H01L 29/24; C30B 33/005; C30B 35/00

(57) ABSTRACT

A method for fabricating a thin film transistor (TFT) is provided, and the method includes following steps. A gate and an insulation layer are sequentially formed on a substrate. A source electrode and a drain electrode are formed on the insulation layer. A solution type metal oxide precursor is coated on the insulation layer above the gate. A gas is provided, and the gas does not react with the solution type metal oxide precursor. An illumination process is performed on the solution type metal oxide precursor, so as to form a metal oxide semiconductor material through a photo cross-linking reaction of the solution type metal oxide precursor.

### CROSS-REFERENCE TO RELATED APPLICATION

This application claims the priority benefit of Taiwan application serial no. 103131192, filed on Sep. 10, 2014. The entirety of the above-mentioned patent application is hereby incorporated by reference herein and made a part of this specification.

### FIELD OF THE INVENTION

The invention relates to a method for fabricating a semiconductor device and an apparatus of fabricating a semiconductor device. More particularly, the invention relates to a method for fabricating a thin film transistor (TFT) and an apparatus of fabricating a TFT.

### DESCRIPTION OF RELATED ART

With recent advancement in information technology, different kinds of displays have been applied as screens of consumer electronic products (e.g., cell phones, notebook computers, digital cameras, personal digital assistants (PDA), and so forth). Having the advantages of light weight, compact size, and low power consumption, liquid crystal displays (LCDs) and organic electroluminescent displays (OELDs or OLEDs) have become the mainstream in the market. In a method for fabricating the LCD or the OLED, a semiconductor device array is arranged on a substrate.

In pursuit of simple manufacturing process and low costs, employing a solution type metal oxide semiconductor to form the TFT is one of the pioneer technology solutions. Nevertheless, the TFT formed by the solution type metal oxide semiconductor is required to undergo a high-temperature (500-600° C.) heating process according to the related art, which creates the cost barrier to manufacturers.

### SUMMARY OF THE INVENTION

The invention is related to a method for fabricating a TFT and an apparatus of fabricating the same. The method and the apparatus are suitable for being applied to bring on a photo catalysis cross-linking reaction of a solution type metal oxide precursor at a low temperature; besides, by applying the method and the apparatus, a TFT characterized by better stability can be formed.

In an embodiment of the invention, a method for fabricating a TFT is provided, and the method includes following steps. A gate and an insulation layer are sequentially formed on a substrate. A source electrode and a drain electrode are formed on the insulation layer. A solution type metal oxide precursor is coated on the insulation layer above the gate. A gas is provided, and the gas does not react with the solution type metal oxide precursor. An illumination process is performed on the solution type metal oxide precursor, so as to form a metal oxide semiconductor material through a photo cross-linking reaction of the solution type metal oxide precursor.

In an embodiment of the invention, an apparatus of fabricating a TFT is provided, and the apparatus includes a chamber, an illumination source, a gas providing device, and a gas exhausting device. The illumination source is located in the chamber and configured to perform an illumination process on a solution type metal oxide precursor on an insulation layer above a gate, so as to form a metal oxide semiconductor material through a photo cross-linking reaction of the solution type metal oxide precursor. The gas providing device is connected to a side wall of the chamber and configured to provide a gas before or during the illumination process, and the provided gas does not react with the solution type metal oxide precursor. The gas exhausting apparatus is connected to another side wall of the chamber.

In view of the above, according to the method for fabricating the TFT provided herein, the illumination process is performed on the solution type metal oxide precursor; therefore, the solution type metal oxide precursor can be transformed into the metal oxide semiconductor material through performing a subsequent low temperature heating process. Additionally, the provided gas does not react with the solution type metal oxide precursor and can prevent other substances from reacting with the solution type metal oxide precursor; hence, the metal oxide semiconductor material having the metal oxide with high bonding density can be formed, and the stability of the resultant TFT can be enhanced.

Several exemplary embodiments accompanied with figures are described in detail below to further describe the invention in details.

### BRIEF DESCRIPTION OF THE DRAWINGS

FIG. 1A through FIG. 1E are schematic diagrams illustrating a method for fabricating a TFT according to a first embodiment of the invention.

FIG. 2A through FIG. 2E are schematic diagrams illustrating a method for fabricating a TFT according to a second embodiment of the invention.

FIG. 3 is a schematic diagram illustrating an apparatus of fabricating a TFT according to an embodiment of the invention.

FIG. 4A and FIG. 4B illustrate current-voltage correlations obtained by performing an electrical test on a TFT according to an experimental example of the invention, given that a positive bias voltage and a negative bias voltage are respectively provided.

FIG. 5A and FIG. 5B illustrate current-voltage correlations obtained by performing an electrical test on a conventional TFT, given that a positive bias voltage and a negative bias voltage are respectively provided.

FIG. 6 illustrates a current-voltage correlation obtained by performing an electrical test on a TFT according to an experimental example of the invention.

FIG. 7 illustrates a current-voltage correlation obtained by performing an electrical test on a conventional TFT.

### DETAILED DESCRIPTION OF DISCLOSED EMBODIMENTS

Several embodiments are described below to illustrate the method for fabricating a TFT.

### First Embodiment

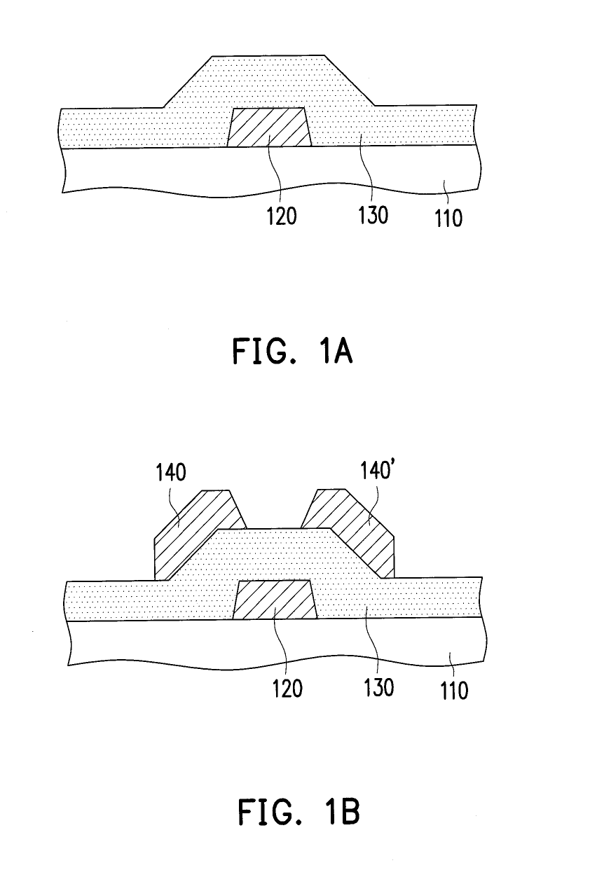

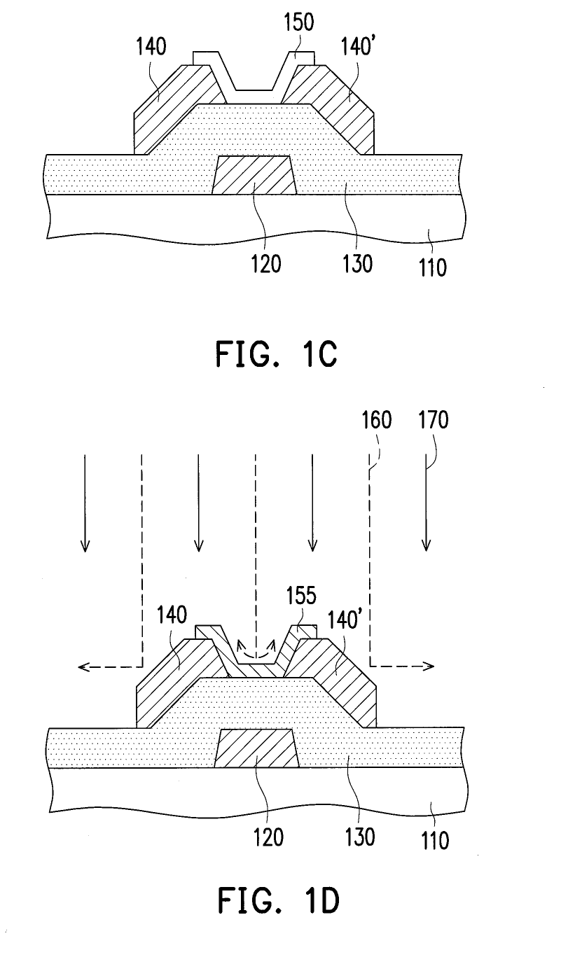

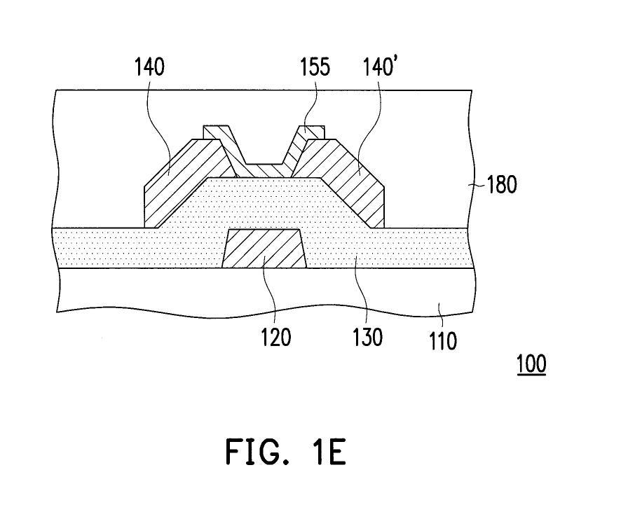

FIG. 1A through FIG. 1E are schematic diagrams illustrating a method for fabricating a TFT according to a first embodiment of the invention. With reference to FIG. 1A, a substrate 110 is provided, and a gate 120 and an insulation layer 130 are sequentially formed on the substrate 110. The substrate 110 is, for instance, a glass substrate, a quart substrate, an organic polymer substrate, a metal substrate, and so forth. The gate 120 is made of metal, metal alloy, metal oxide, metal nitride, or a combination thereof, for instance. Preferably, the gate 120 is made of titanium (Ti)-tungsten (W) alloy with the thickness from about 280 nm to about 350 nm, and a method for forming the gate 120 may include a chemical/physical vapor deposition (CVD/PVD) process and a patterning process. The insulation layer 130 is made of silicon oxide or silicon nitride with the thickness from about 300 nm to about 350 nm, for instance, and a method for forming the insulation layer 130 may include a thermal oxidization film formation process or a CVD process.

With reference to FIG. 1B, a source electrode 140 and a drain electrode 140′ are formed on the insulation layer 130. The source electrode 140 and the drain electrode 140′ are made of metal, metal alloy, metal oxide, metal nitride, or a combination thereof. In particular, the source electrode 140 and the drain electrode 140′ may be made of indium tin oxide (ITO) with the thickness from about 75 nm to about 150 nm, and a method for forming the source electrode 140 and the drain electrode 140′ may include a CVD/PVD process.

With reference to FIG. 1C, a solution type metal oxide precursor 150 is coated on the insulation layer 130 above the gate 120. In the present embodiment, the source electrode 140 and the drain electrode 140′ are formed on the insulation layer 130, and then the solution type metal oxide precursor 150 is coated on the insulation layer 130; therefore, a portion of the solution type metal oxide precursor 150 is formed on the insulation layer 130 between the source electrode 140 and the drain electrode 140′, and the other portion of the solution type metal oxide precursor 150 is formed on the source electrode 140 and the drain electrode 140′. In the structure shown in FIG. 1C, the source electrode 140, the drain electrode 140′, and the solution type metal oxide precursor 150 may be coplanar; however, the invention is not limited thereto. That is, the solution type metal oxide precursor 150 may be formed only on the insulation layer 130 between the source electrode 140 and the drain electrode 140′ but not on the source electrode 140 and the drain electrode 140′ (which is not shown in the drawings). Specifically, the solution type metal oxide precursor 150 is a precursor material that is applied to subsequently form a channel between the source electrode 140 and the drain electrode 140′, and hence the arrangement of the solution type metal oxide precursor 150 is not limited in the present embodiment; as long as the solution type metal oxide precursor 150 is arranged in a manner to allow the source electrode 140 to be connected to the drain electrode 140′, such arrangement falls within the scope of protection provided in the invention.

For instance, the solution type metal oxide precursor 150 is a material formed by dissolving an organic and/or inorganic metal precursor in an organic solvent, and such a material can be transformed into metal oxide after being irradiated by ultraviolet light. For instance, the solution type metal oxide precursor 150 may include 2-methoxyl ethanol, metal halide, metal acetate, or metal nitrate; alternatively, the solution type metal oxide precursor 150 is mainly composed of 2-methoxyl ethanol, metal halide, metal acetate, or metal nitrate.

With reference to FIG. 1D, a gas 160 is provided. The gas 160 does not react with the solution type metal oxide precursor 150, and parts of the gas 160 are in contact with the solution type metal oxide precursor 150. The gas 160 includes an inert gas, nitrogen, or any other type of gas which does not react with the solution type metal oxide precursor 150; alternatively, the gas 160 is mainly composed of an inert gas, nitrogen, or any other type of gas which does not react with the solution type metal oxide precursor 150. During the process of providing the gas 160, a flow rate of the provided gas 160 is between 100 m³/hr and 500 m³/hr.

According to the present embodiment, an illumination process 170 is performed on the solution type metal oxide precursor 150 during the process of providing the gas 160, so as to form a metal oxide semiconductor material 155 through a photo cross-linking reaction of the solution type metal oxide precursor 150. Here, the metal oxide semiconductor material 155 is applied to form the channel between the source electrode 140 and the drain electrode 140′. However, the invention is not limited thereto, and the illumination process 170 may be performed on the solution type metal oxide precursor 150 after the gas 160 is provided. The illumination process is performed to bring on the photo catalysis cross-linking reaction (i.e., the photo cross-linking reaction); in case that the photo catalysis cross-linking reaction is incomplete, the bonding density of the metal ions and oxygen ions of the metal oxide may be excessively low, and the stability of the resultant TFT may be insufficient.

Once the illumination process 170 is performed to bring on the photo cross-linking reaction for transforming the solution type metal oxide precursor 150 into the metal oxide semiconductor material 155, reactive substances (e.g., ozone) may be generated. Such reactive substances may react with the solution type metal oxide precursor 150 and/or the metal oxide semiconductor material 155, which results in formation of unnecessary by-products.

If the gas 160 is provided before or during the illumination process 170, the provided gas 160 may take the reactive substances (e.g., ozone) away, so as to prevent the solution type metal oxide precursor 150 and/or the metal oxide from reacting with the reactive substances (e.g., ozone) and from generating the unnecessary by-products. Hence, the provided gas 160 that takes away the reactive substances may ensure the high bonding density of the resultant metal oxide semiconductor material 155 and thus enhance the stability of the TFT 100. The light employed in the illumination process 170 is the ultraviolet light with wavelengths of 185 nm and/or 254 nm, and the intensities of the ultraviolet light with wavelengths of 185 nm and/or 254 nm are 4.1 mW/cm² and 22 mW/cm², respectively. The illumination process 170 lasts for 5-10 minutes in total, and thereby the solution type metal oxide precursor 150 can be transformed into the metal oxide semiconductor material 155 through the photo cross-linking reaction.

According to the present embodiment, while the gas 160 is being provided, a gas exhausting process may be further performed, such that the gas 160 is removed from the solution type metal oxide precursor 150 or the metal oxide semiconductor material 155, and an amount the exhaust gas in the gas exhausting process is between 100 m³/hr and 500 m³/hr, for instance. Said gas exhausting process may further allow the reactive substances generated through the photo cross-linking reaction to be removed from the solution type metal oxide precursor 150 or the metal oxide semiconductor material 155. In the present embodiment, after the metal oxide semiconductor material 155 is formed, a sintering process may be further performed on the metal oxide semiconductor material 155, so as to enhance the bonding density of the metal oxide in the metal oxide semiconductor material 155. Here, the sintering process is performed at 350° C. or at a lower temperature for about an hour, for instance.

With reference to FIG. 1E, an organic insulation layer 180 is formed on the substrate 110, and the organic insulation layer 180 is made of polyester (PET), polyolefin, polypropylene, polycarbonate, polyalkylene oxide, polystyrene, polyether, polyketone, polyalcohol, polyaldehyde, any other appropriate material, or a combination thereof. All the remaining manufacturing steps of the TFT 100 are then implemented according to the related art to form the TFT 100, and the resultant TFT can be applied in various manners. For instance, an ITO layer connected to an external circuit can be formed on the drain electrode 140′, such that the TFT 100 may serve as an active device in a display panel.

In the present embodiment of the invention, the gas that does not react with the solution type metal oxide precursor is provided before or during the illumination process, and thus the provided gas may take the reactive substances away while the solution type metal oxide precursor is being transformed into the metal oxide semiconductor material, so as to prevent the solution type metal oxide precursor or the resultant metal oxide from reacting with the reactive substances and from generating the unnecessary by-products. Additionally, the bonding density of the metal oxide in the metal oxide semiconductor material can be increased, and the stability of TFT can be further enhanced.

### Second Embodiment

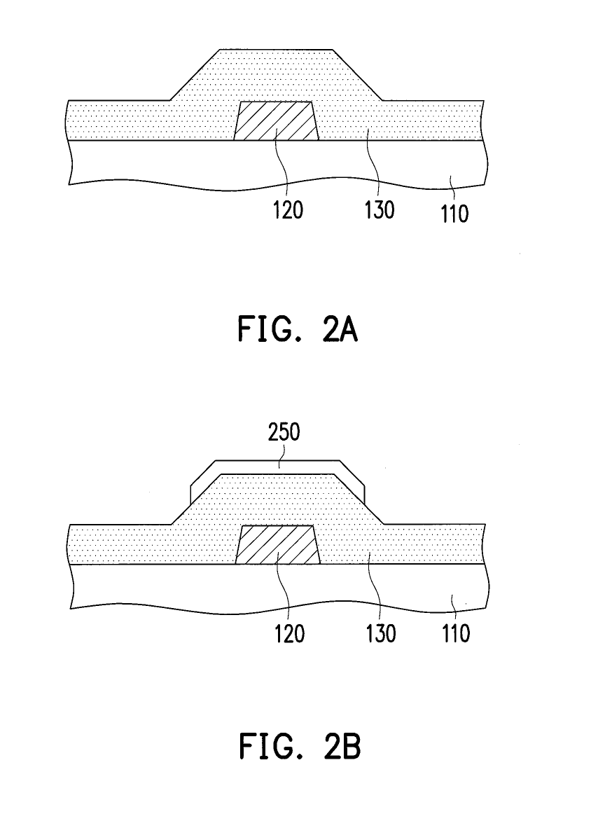

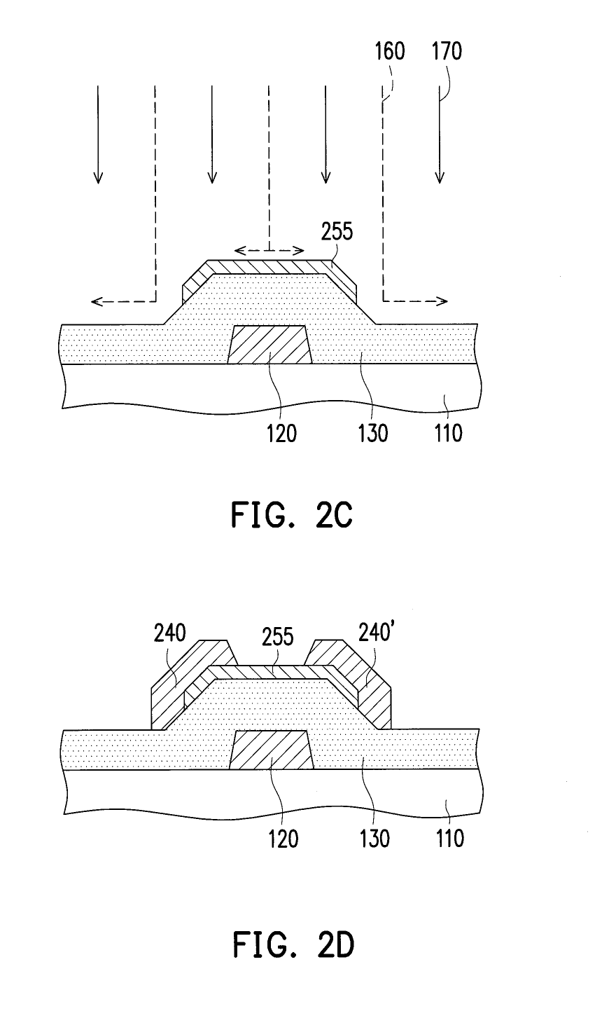

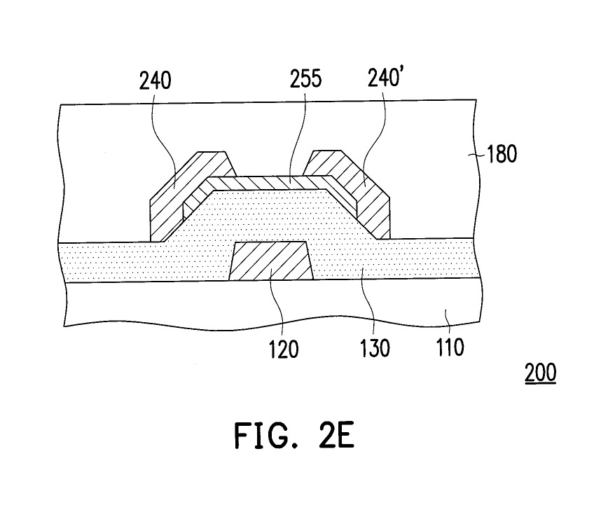

FIG. 2A through FIG. 2E are schematic diagrams illustrating a method for fabricating a TFT according to a second embodiment of the invention. With reference to FIG. 2A, a substrate 110 is provided, and a gate 120 and an insulation layer 130 are sequentially formed on the substrate 110.

With reference to FIG. 2B, a solution type metal oxide precursor 250 is coated on the insulation layer 130 above the gate 120. Similar to the solution type metal oxide precursor described in the first embodiment, the solution type metal oxide precursor 250 may include 2-methoxyl ethanol, metal halide, metal acetate, or metal nitrate.

With reference to FIG. 2C, a gas 160 is provided, and the gas 160 does not react with the solution type metal oxide precursor 250. The gas 160 includes an inert gas, nitrogen, or any other type of gas which does not react with the solution type metal oxide precursor 250; alternatively, the gas 160 is mainly composed of an inert gas, nitrogen, or any other type of gas which does not react with the solution type metal oxide precursor 250. Here, a flow rate of the provided gas 160 is between 100 m³/hr and 500 m³/hr. During and/or after the process of providing the gas 160, an illumination process 170 is performed on the solution type metal oxide precursor 250, so as to form a metal oxide semiconductor material 255 through a photo cross-linking reaction of the solution type metal oxide precursor 250. Here, the metal oxide semiconductor material 255 is applied to form the channel between the source electrode 140 and the drain electrode 140′. According to the present embodiment, while the gas 160 is being provided, a gas exhausting process may be further performed, such that the gas 160 and reactive substances are removed from the solution type metal oxide precursor 250 and/or the metal oxide semiconductor material 255, and an amount the exhaust gas in the gas exhausting process is between 100 m³/hr and 500 m³/hr, for instance.

With reference to FIG. 2D, a source electrode 240 and a drain electrode 240′ are formed on the insulation layer, and the metal oxide semiconductor material 255, the source electrode 240, and the drain electrode 240′ may constitute a back channel etch (BCE) structure. The arrangement described herein is different from that provided in the previous embodiment, whereas the materials and the thicknesses of the source electrode 240 and the drain electrode 240′ provided herein are similar to those of the source electrode 140 and the drain electrode 140′ described in the previous embodiment. Hence, no further descriptions in this regard are provided below.

The difference between the present embodiment and the first embodiment mainly lies in that the solution type metal oxide precursor 250 is formed on the insulation layer 130, the solution type metal oxide precursor 250 is transformed into the metal oxide semiconductor material 255, and then the source electrode 240 and the drain electrode 240′ are formed on the insulation layer 130. Hence, a portion of the source electrode 240 and a portion of the drain electrode 240′ are located on the metal oxide semiconductor material 255, and the metal oxide semiconductor material 255 acts as the channel between the source electrode 240 and the drain electrode 240′ and connects the source electrode 240 to the drain electrode 240′.

With reference to FIG. 2E, an organic insulation layer 180 acting as a planarization layer is formed on the substrate 110. All the remaining manufacturing steps of the TFT 200 are then implemented according to the related art to form the TFT 200, and the resultant TFT can be applied in various manners.

In the previous embodiments, the method for manufacturing the TFT is applied to the TFT with the coplanar structure or the BCE stricture, while the invention is not limited thereto. For instance, the method for manufacturing the TFT provided herein may be applied to a structure having a etch stop layer/channel protecting layer. In the structure, the source electrode and the drain electrode are located above the metal oxide semiconductor material film, and an etch stop layer is arranged between the metal oxide semiconductor material film and the source and the drain electrodes.

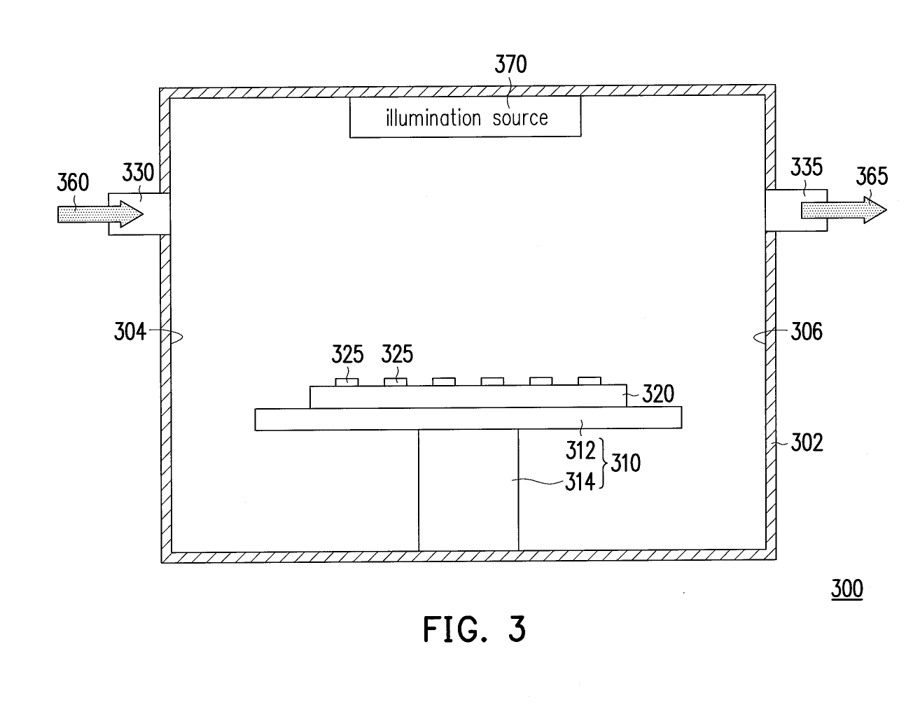

An apparatus of manufacturing the TFT provided herein is explained below with reference to FIG. 3.

FIG. 3 is a schematic diagram illustrating an apparatus of fabricating a TFT according to an embodiment of the invention. As shown in FIG. 3, an apparatus 300 of fabricating a TFT is provided, and the apparatus 300 includes a chamber 302, an illumination source 370, a gas providing device 330, and a gas exhausting device 335. The chamber 302 has a side wall 304 and a side wall 306, and a carrier 310 is arranged in the chamber 302. The carrier 310 has a support member 314 and a support stage 312, and the substrate 320 is located on the support stage 312. The substrate 320 has a plurality of TFTs 325 thereon; here, the substrate 320 is a glass substrate, a quartz substrate, an organic polymer substrate, a metal substrate, and so on. The TFT 325 described herein may be the TFT 100 provided in the first embodiment and/or the TFT 200 provided in the second embodiment.

According to the present embodiment, if the TFT 325 is the TFT 100 provided in the first embodiment, the TFT 325 may include the gate, the insulation layer covering the gate, the source electrode, and the drain electrode. The source electrode and the drain electrode are located on the insulation layer, and the solution type metal oxide precursor is coated on a region between the source electrode and the drain electrode. Here, the solution type metal oxide precursor includes 2-methoxyl ethanol, metal halide, metal acetate, or metal nitrate, for instance. By contrast, if the TFT 325 is the TFT 200 provided in the second embodiment, the TFT 325 may include the gate and the insulation layer covering the gate, and the solution type metal oxide precursor may be coated on the insulation layer above the gate. Besides, the size of the TFT 325 is exaggerated in FIG. 3 for illustrative purposes, while the depicted size is merely exemplary and should not be construed as a limitation to the invention.

The illumination source 370 is located in the chamber 302 and configured to perform an illumination process on the solution type metal oxide precursor on the insulation layer above the gate, so as to form a metal oxide semiconductor material through a photo cross-linking reaction of the solution type metal oxide precursor. For instance, the illumination source 370 is able to emit the ultraviolet light with wavelengths of 185 nm and/or 254 nm, and the intensities of the ultraviolet light with wavelengths of 185 nm and/or 254 nm are 4.1 mW/cm² and 22 mW/cm², respectively.

One end of the gas providing device 330 is connected to the side wall 304 of the chamber 302, and the other end of the gas providing device 330 is connected to a gas supply (not shown). The gas providing device 330 is configured to provide a gas 360 before or during the illumination process, and the provided gas 360 does not react with the solution type metal oxide precursor. Here, the gas 360 is an inert gas or nitrogen, for instance. A flow rate of the gas 360 provided by the gas providing device 330 is 100-500 m³/hr, for instance.

One end of the gas exhausting device 335 is connected to the side wall 306 of the chamber 302, and the other end of the gas exhausting device 335 is connected to a gas collection device (not shown) or atmosphere. During the process of introducing the gas 360 into the chamber 302 with use of the gas providing device 330, the gas exhausting device 335 may be simultaneously applied to perform the gas exhausting process, so as to exhaust a mixed gas 365 containing the gas 360 and other gases (including the reactive substances generated through the photo cross-linking reaction and generated in the normal environment) from the chamber 302. Here, an amount the gas exhausted by the gas exhausting device 335 is between 100 m³/hr and 500 m³/hr, for instance.

In the apparatus of fabricating the TFT provided herein, the illumination source may emit the light with the specific wavelength, which enables the photo cross-linking reaction of the solution type metal oxide precursor on the TFT; thereby, the metal oxide semiconductor material is formed. Besides, the gas providing device in the apparatus of fabricating the TFT provided in the present embodiment may provide the inert gas or nitrogen, and the provided gas may take the reactive substances away, so as to prevent the solution type metal oxide precursor and/or the metal oxide semiconductor material from reacting with the reactive substances; as a result, the metal oxide semiconductor material having the metal oxide with high bonding density can be formed, and the stability of the TFT can be enhanced.

### EXAMPLE

An experimental example and a reference example are provided below to explain the properties of the TFT.

### Experimental Example

The TFT provided in the experimental example is formed by performing the method described in the first embodiment. Particularly, 2-methoxyl ethanol and metal halide serve as the solution type metal oxide precursor, and the ultraviolet light with the wavelengths of 185 nm and 254 nm (whose intensities are 4.1 mW/cm² and 22 mW/cm², respectively) is applied to irradiate the solution type metal oxide precursor for about 10 minutes, such that the solution type metal oxide precursor is transformed into the metal oxide semiconductor material as the channel between the source electrode and the drain electrode. In addition, during the ultraviolet light illumination process, the nitrogen having the flow rate of 100-500 m³/hr is provided.

### Reference Example

The TFT provided in the reference example is formed by performing the same method as that provided in the experimental example, while no nitrogen is provided in the reference example.

### [Bonding Density of Metal Oxide]

An XPA analysis of the metal oxide semiconductor material in the TFT provided respectively in the experimental example and the reference example is conducted to measure the bonding density of metal and oxygen ions in the metal oxide semiconductor material, and the measured results are recorded in Table 1 below. Here, the unit of the bonding density of oxide shown in Table 1 is atomic percentage (at %).

TABLE 1

| | | Density of | Density of | Density of |
|---|---|---|---|---|
| | | oxygen | oxygen | impurities |
| | | ions | ions not | resulting from |
| | | bonded to | bonded to | incomplete |
| | Analysis | metal ions | metal ions | reaction |
| | Depth (nm) | (at %) | (at %) | (at %) |
| Experimental | 0.42 | 61.1 | 23.5 | 15.4 |
| Example | | | | |
| Reference | 0.42 | 61.6 | 20.2 | 18.2 |
| Example | | | | |

According to Table 1, the metal oxide semiconductor material has the relatively low density of impurities if the nitrogen is provided; the lower the density of impurities, the greater the stability of metal oxide semiconductor material. This may be further proven by the following assessment results of electrical properties. Besides, in the metal oxide semiconductor material described in the experimental example, the density of oxygen ions not bonded to the metal ions is relatively high, which indicates that the metal oxide semiconductor material can provide the relatively high carrier concentration and thus achieve the relatively high electron mobility rate. The resultant TFT can accordingly achieve the relatively high electron mobility rate as well.

### [Assessment Result 1 of Electrical Properties]

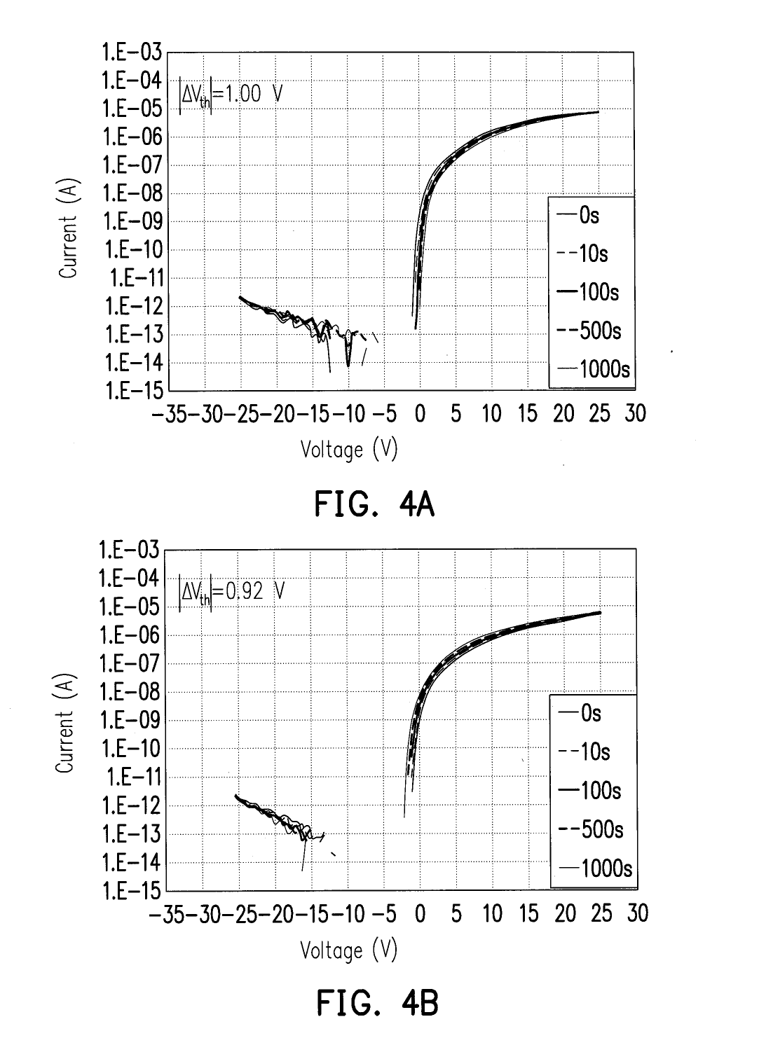

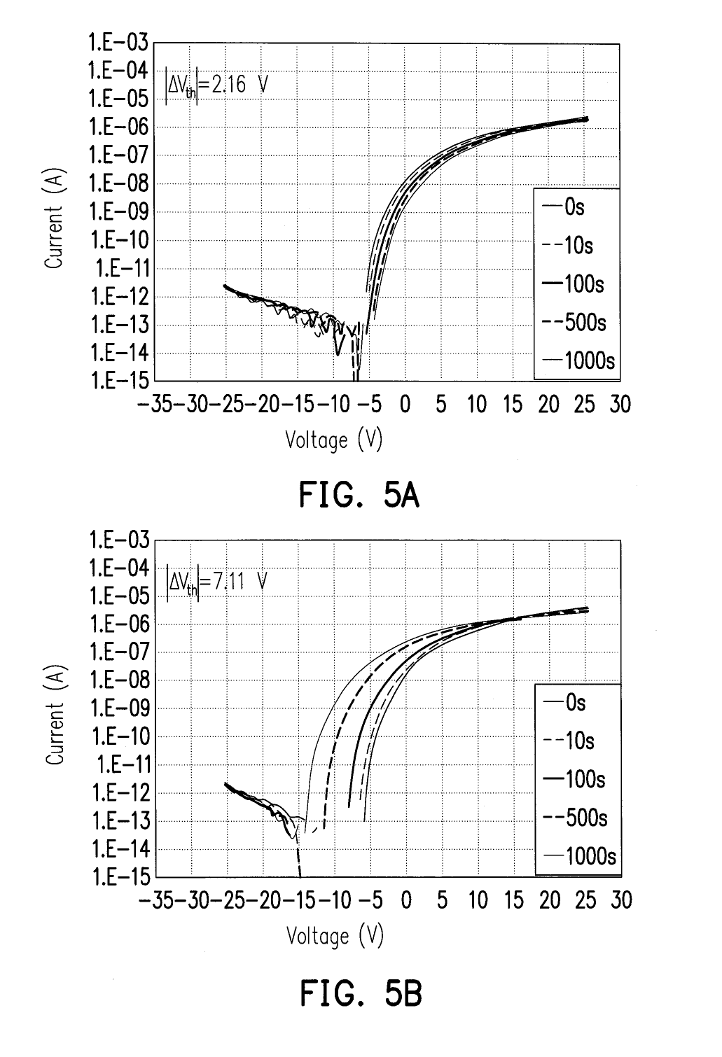

At the room temperature, a negative bias voltage (−30 V gate voltage) or a positive bias voltage (30 V gate voltage) is applied to the TFT provided in the experimental example and the reference example for 1000 seconds, and the obtained current is measured to assess the electrical properties of voltage shift. The measured current is recorded, as shown in FIG. 4A to FIG. 4B and FIG. 5A to FIG. 5B, respectively.

FIG. 4A and FIG. 4B illustrate current-voltage correlations obtained by performing an electrical test on a TFT according to an experimental example of the invention, given that a positive bias voltage and a negative bias voltage are respectively provided. FIG. 5A and FIG. 5B illustrate current-voltage correlations obtained by performing an electrical test on a conventional TFT, given that a positive bias voltage and a negative bias voltage are respectively provided. Note that the fabricating method provided in the embodiments of the invention is not applied. With reference to FIG. 4A and FIG. 5A, given that the positive bias voltage is provided, the absolute value |ΔVth| of the voltage shift of the TFT provided in the experimental example (i.e., nitrogen is provided) is about 1 V, and such an absolute value is less than the absolute value 2.16 V of the voltage shift of the conventional TFT. With reference to FIG. 4B and FIG. 5B, given that the negative bias voltage is provided, the absolute value |ΔVth| of the voltage shift of the TFT provided in the experimental example is about 0.92 V, and such an absolute value is less than the absolute value 7.11 V of the voltage shift of the conventional TFT.

In view of the above, the metal oxide semiconductor material of the TFT described herein has high carrier concentration and low density of impurities, and thus the electrical properties of the TFT provided in the experimental example are rather stable.

### [Assessment Result 2 of Electrical Properties]

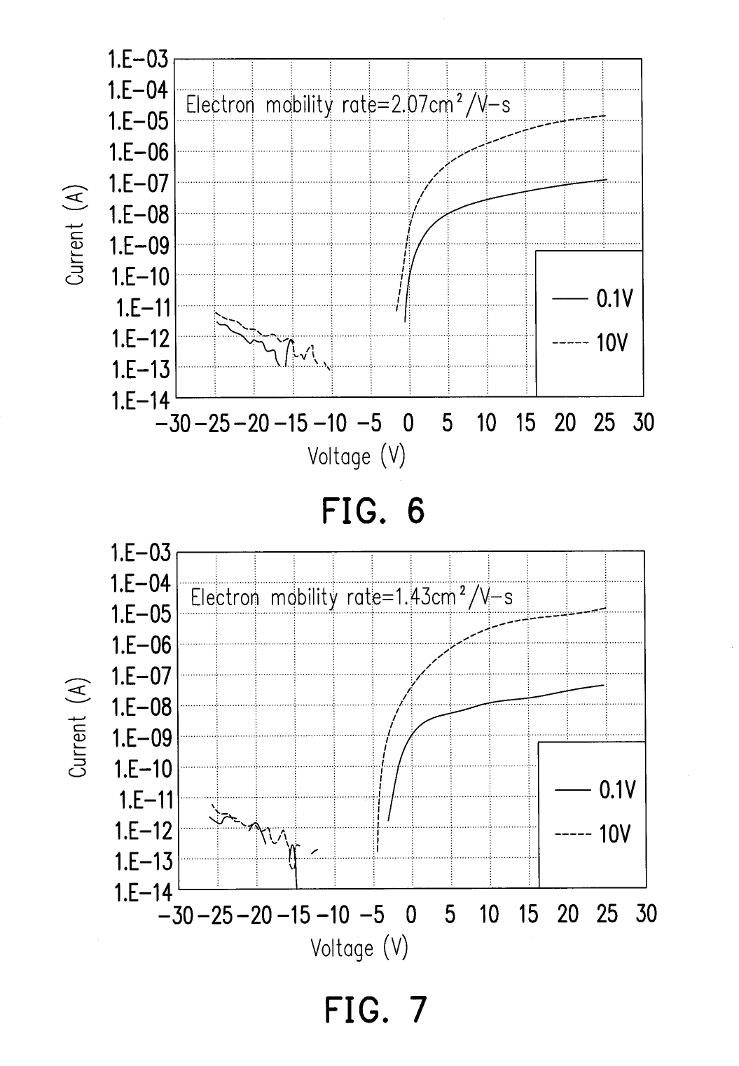

A gate voltage (within a range from −30 V to 30V) is applied to the TFT provided in the experimental example and the reference example, and simultaneously a 0.1-V voltage (shown by solid lines) and a 10-V voltage (shown by dashed lines) are provided to the source electrode. The obtained current is then measured to assess the electrical properties of the electron mobility rate and is recorded, as shown in FIG. 6 and FIG. 7, respectively.

FIG. 6 illustrates a current-voltage correlation obtained by performing an electrical test on a TFT according to an experimental example of the invention. FIG. 7 illustrates a current-voltage correlation obtained by performing an electrical test on a conventional TFT. Note that the fabricating method provided in the embodiments of the invention is not applied. With reference to FIG. 6 and FIG. 7, the electron mobility rate of the TFT is 2.07 cm²/V-s according to the experimental example and is higher than the electron mobility rate of the TFT (1.43 cm²/V-s) according to the reference example. It can thus be learned that the TFT formed through introducing nitrogen has the relatively high electron mobility rate.

To sum up, according to the method for fabricating the TFT provided herein, the illumination process is performed on the solution type metal oxide precursor; therefore, the solution type metal oxide precursor can be transformed into the metal oxide semiconductor material through performing a subsequent low temperature heating process in no need of performing the subsequent high-temperature heating process. Additionally, the gas that does not react with the solution type metal oxide precursor is provided before or during the illumination process, and thus the provided gas may prevent the solution type metal oxide precursor and/or the resultant metal oxide from reacting with the reactive substances and from generating the unnecessary by-products. Besides, the bonding density of the metal oxide in the metal oxide semiconductor material can be increased, and the stability of TFT can be further enhanced.

From another perspective, the apparatus of fabricating the TFT provided herein is equipped with the illumination source that may emit the light with the specific wavelength, so as to enable the photo cross-linking reaction of the solution type metal oxide precursor on the TFT; thereby, the metal oxide semiconductor material can be formed. Moreover, the apparatus of fabricating the TFT provided herein is also equipped with the gas providing device that may provide the inert gas or nitrogen; hence, the apparatus may be employed to form the TFT characterized by superior stability.

Although the invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

What is claimed is:

1. A method for fabricating a thin film transistor, the method comprising:
sequentially forming a gate and an insulation layer on a substrate;
forming a source electrode and a drain electrode on the insulation layer;
coating a solution type metal oxide precursor on the insulation layer above the gate;
providing a gas, wherein the gas does not react with the solution type metal oxide precursor; and
performing an illumination process on the solution type metal oxide precursor, so as to form a metal oxide semiconductor material through a photo cross-linking reaction of the solution type metal oxide precursor.

2. The method according to claim 1, wherein the gas comprises an inert gas and/or nitrogen.

3. The method according to claim 2, further comprising performing a gas exhausting process during the illumination process, such that the gas is removed from the solution type metal oxide precursor or the metal oxide semiconductor material, and an amount the exhaust gas in the gas exhausting process is between 100 m³/hr and 500 m³/hr.

4. The method according to claim 2, wherein the solution type metal oxide precursor comprises 2-methoxyl ethanol, metal halide, metal acetate, or metal nitrate.

5. The method according to claim 2, wherein after forming the source electrode and the drain electrode on the insulation layer, the solution type metal oxide precursor is formed on the insulation layer between the source electrode and the drain electrode.

6. The method according to claim 2, wherein the solution type metal oxide precursor is formed on the insulation layer and is transformed into the metal oxide semiconductor material, and then the source electrode and the drain electrode are formed on the insulation layer.

7. The method according to claim 1, wherein a flow rate of the provided gas is between 100 m³/hr and 500 m³/hr.

8. The method according to claim 1, further comprising performing a gas exhausting process during the illumination process, such that the gas is removed from the solution type metal oxide precursor or the metal oxide semiconductor material, and an amount the exhaust gas in the gas exhausting process is between 100 m³/hr and 500 m³/hr.

9. The method according to claim 1, wherein the solution type metal oxide precursor comprises 2-methoxyl ethanol, metal halide, metal acetate, or metal nitrate.

10. The method according to claim 1, wherein after forming the source electrode and the drain electrode on the insulation layer, the solution type metal oxide precursor is formed on the insulation layer between the source electrode and the drain electrode.

11. The method according to claim 1, wherein the solution type metal oxide precursor is formed on the insulation layer and is transformed into the metal oxide semiconductor material, and then the source electrode and the drain electrode are formed on the insulation layer.

12. An apparatus for fabricating a thin film transistor, comprising:
a chamber;
an illumination source located in the chamber and configured to perform an illumination process on a solution type metal oxide precursor on an insulation layer above a gate, so as to form a metal oxide semiconductor material through a photo cross-linking reaction of the solution type metal oxide precursor;
a gas providing device connected to a side wall of the chamber and configured to provide a gas before or during the illumination process, wherein the gas does not react with the solution type metal oxide precursor; and
a gas exhausting device connected to another side wall of the chamber.

13. The apparatus according to claim 12, wherein the thin film transistor comprises the gate, the insulation layer covering the gate, a source electrode, and a drain electrode, the source electrode and the drain electrode are located on the insulation layer, and the solution type metal oxide precursor is coated on a region between the source electrode and the drain electrode.

14. The apparatus according to claim 12, wherein the thin film transistor comprises the gate and the insulation layer covering the gate, and the solution type metal oxide precursor is coated on the insulation layer above the gate.

15. The apparatus according to claim 12, wherein the gas comprises an inert gas and/or nitrogen.

16. The apparatus according to claim 12, wherein a flow rate of the gas provided by the gas providing device is between 100 m³/hr and 500 m³/hr.

17. The apparatus according to claim 12, wherein an amount of the gas exhausted by the gas exhausting device is between 100 m³/hr and 500 m³/hr.

18. The apparatus according to claim 12, wherein the solution type metal oxide precursor comprises 2-methoxyl ethanol, metal halide, metal acetate, or metal nitrate.

19. A apparatus configured to perform the method as claimed in claim 1 for fabricating the thin film transistor.

20. The apparatus according to claim 19, wherein the gas comprises an inert gas and/or nitrogen.
